(19) United States
(12) Patent Application Publication
(10) Pub. No.: US 2022/0413031 A1
(43) Pub. Date: Dec. 29, 2022

(54) LINE DOUBLE-END STEADY-STATE QUANTITY DISTANCE MEASURING METHOD AND SYSTEM BASED ON AMPLITUDE-COMPARISON PRINCIPLE

(71) Applicants: CHINA ELECTRIC POWER RESEARCH INSTITUTE COMPANY LIMITED, Beijing (CN); STATE GRID CORPORATION OF CHINA, Beijing (CN)

(72) Inventors: Yarong GUO, Beijing (CN); Xingguo WANG, Beijing (CN); Zexin ZHOU, Beijing (CN); Ying LIANG, Beijing (CN); Guosheng YANG, Beijing (CN); Huanzhang LIU, Wuhan (CN); Dingxiang DU, Beijing (CN); Yong LI, Wuhan (CN); Shuyang WANG, Beijing (CN); Qi CHENG, Beijing (CN); Hong CAO, Beijing (CN); Zhengguang CHEN, Beijing (CN)

(21) Appl. No.: 17/779,647

(22) PCT Filed: Jul. 8, 2020
(86) PCT No.: PCT/CN2020/100844

§ 371 Date: May 25, 2022

(30) Foreign Application Priority Data
Jan. 17, 2020 (CN) 202010053618.X

(51) Int. Cl. G01R 31/08

(52) U.S. Cl. CPC G01R 31/085

(57) ABSTRACT

A line double-end steady-state quantity distance measuring method and system based on an amplitude-comparison principle. According to the method and system, voltage values and current values of both sides of a line before and after a fault are collected (102), a voltage variable quantity and a current variable quantity of both sides of the line are calculated (103), and after a voltage phasor value and a current phasor value are determined according to the voltage variable quantity and the current variable quantity (104), the position of a short-circuit point is determined by performing iterative calculation on the voltage of the short-circuit point. The method is simple in principle, and can accurately recognize a fault point, achieving precise distance measurement of lines.

### CROSS-REFERENCE TO RELATED APPLICATION

This application claims priority to China patent application No. 202010053618.X, filed with China national intellectual property administration on Jan. 17, 2020, the disclosure of which is hereby incorporated by reference in its entirety.

### TECHNICAL FIELD

The present disclosure relates to the field of relay protection, and relates to, for example, a line double-end steady-state quantity distance measuring method and system based on an amplitude-comparison principle.

### BACKGROUND

In areas with diverse and complex topography, transmission lines are usually spread between mountains and rivers, and are often set in a manner of overhead lines. In addition, in response to a special situation of transmission lines crossing over ultra-wide waterways and straits, there has also been an ultra-high-voltage overhead line-cable hybrid line. With the complexity of a power transmission network, quickly and accurately determining a position of a fault point of a high-voltage line and timely solving the problems and eliminating potential safety hazards are of great significance to ensure the safety of a power system.

For detection of high-voltage transmission line faults, methods in related technologies have been proposed at home and abroad, such as an impedance method based on power frequency electrical quantities, a fault analysis method, and a traveling wave method based on transient-state components. However, since electrical parameters of cables are different from those of overhead transmission lines, the fault characteristics of the hybrid line are different from those of a conventional line to a certain extent. Therefore, the accuracy of a fault distance measuring method for an overhead transmission line in the related technology will be correspondingly affected, such that a new distance measuring method needs to be provided.

### SUMMARY

The present disclosure provides a line double-end steady-state quantity distance measuring method and system based on an amplitude-comparison principle, which can solve the technical problem that there is a relatively large error in fault positioning due to the fact that the fault positioning carried out on a high-voltage overhead line-cable hybrid line based on power frequency electrical quantities is easily affected by external unstable factors.

The present disclosure provides a line double-end steady-state quantity distance measuring method based on an amplitude-comparison principle. The method includes:

at step 1, collecting voltage values and current values, after an overhead line-cable hybrid transmission line is faulted, of both sides of the line, and voltage values and current values of both sides of the line of one cycle before the line is faulted; here both sides of the line are respectively a side M and a side N;

at step 2, determining voltage value variations according to the collected voltage values of both sides of the line before and after the line is faulted, and determining current value variations according to the collected current values of both sides of the line before and after the line is faulted;

at step 3, calculating voltage phasor values of both sides of the line by performing Fourier transformation on the voltage value variations of both sides of the line, and calculating current phasor values of both sides of the line by performing the Fourier transformation on the current value variations of both sides of the line;

at step 4, calculating voltages Δ\dot{U}φ_{Mxi} and Δ\dot{U}_{φNxi} of a compensation point according to a distance xᵢ from the compensation point to the side M of the line after the line is faulted, the voltage phasor values and the current phasor values of both sides of the line, a length L₁ of an overhead line on the side M, a length L₃ of an overhead line on the side N, a length L₂ of a cable, a wave impedance Z_{cT} and a propagation coefficient γ_{T} of the overhead line, and a wave impedance Z_{cC} and a current propagation coefficient γ_{C} of the cable; here an initial value of i is 1, and φ is any phase in a three-phase circuit, φ=A,B,C;

at step 5, determining a distance xᵢ₊₁ from the compensation point to the side M of the line based on a set distance measuring model according to the voltages Δ\dot{U}_{φMxi} and Δ\dot{U}_{φNxi} of the compensation point; and

at step 6, setting i=i+1; determining that a distance measuring result is a distance x_{N+1} from the compensation point to the side M of the line in case of i>R; and turning back to the step 4 in case of i≤R; here R is a number of iterations.

The present disclosure further provides a line double-end steady-state quantity distance measuring system based on an amplitude-comparison principle. The system includes:

a data acquisition unit, configured to collect voltage values and current values, after an overhead line-cable hybrid transmission line is faulted, of both sides of the line, and voltage values and current values of both sides of the line of one cycle before the line is faulted; here both sides of the line are respectively a side M and a side N;

a first calculation unit, configured to determine voltage value variations according to the collected voltage values of both sides of the line before and after the line is faulted, and determine current value variations according to the collected current values of both sides of the line before and after the line is faulted;

a second calculation unit, configured to calculate voltage phasor values of both sides of the line by performing Fourier transformation on the voltage value variations of both sides of the line, and calculate current phasor values of both sides of the line by performing the Fourier transformation on the current value variations of both sides of the line;

a third calculation unit, configured to calculate voltages Δ\dot{U}_{φMxi} and Δ\dot{U}_{φNxi} of a compensation point according to a distance xᵢ from the compensation point to the side M of the line after the line is faulted, the voltage phasor values and the current phasor values of both sides of the line, a length L₁ of an overhead line on the side M, a length L₃ of an overhead line on the side N, a length L₂ of a cable, a wave impedance Z_{cT} and a propagation coefficient γ_{T} of the overhead line, and a wave impedance Z_{cC} and a current propagation coefficient γ_{C} of the cable; here an initial value of i is 1, and φ is any phase in a three-phase circuit, φ=A,B,C; and

a result determination unit, configured to determine a distance xᵢ₊₁ from the compensation point to the side M of the line based on a set distance measuring model according to the voltages Δ\dot{U}_{φMxi} and Δ\dot{U}_{φNxi} of the compensation point, set i=i+1, determine that a distance measuring result is a distance x_{N+1} from the compensation point to the side M of the line in case of i>R, and turn back to the third calculation unit in case of i≤R; here R is a number of iterations.

### BRIEF DESCRIPTION OF THE DRAWINGS

The exemplary implementation modes of the present disclosure can be understood more completely by referring to the following accompanying drawings:

FIG. 1 is a flow chart of a line double-end steady-state quantity distance measuring method based on an amplitude-comparison principle according to an optional implementation mode of the present disclosure.

FIG. 2 is a schematic diagram of an overhead line-cable hybrid line according to an optional implementation mode of the present disclosure.

FIG. 3 is a schematic structural diagram of a line double-end steady-state quantity distance measuring system based on an amplitude-comparison principle according to an optional implementation mode of the present disclosure.

### DETAILED DESCRIPTION

The exemplary implementation modes of the present disclosure will now be described with reference to the accompanying drawings. However, the present disclosure can be implemented in many different forms and is not limited to the embodiments described here. These embodiments are provided to disclose the present disclosure in detail and completely, and fully convey the scope of the present disclosure to those skilled in the art. The terms in the exemplary implementation modes illustrated in the accompanying drawings do not limit the present disclosure. In the drawings, the same units/elements use the same reference signs.

Unless otherwise specified, the terms (including scientific and technological terms) used herein have the usual meanings to those skilled in the art. In addition, it can be understood that the terms defined in commonly used dictionaries should be understood as having consistent meanings in the context of their related art, and should not be understood as idealized or overly formal meanings.

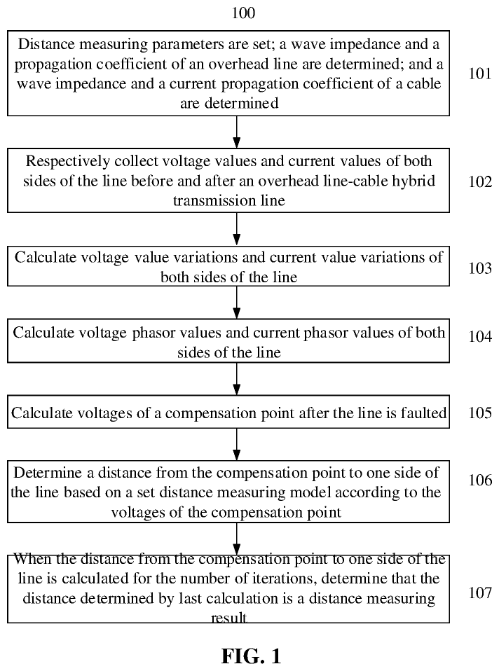

FIG. 1 is a flow chart of a line double-end steady-state quantity distance measuring method based on an amplitude-comparison principle according to an optional implementation mode of the present disclosure. As illustrated in FIG. 1, the line double-end steady-state quantity distance measuring method 100 based on the amplitude-comparison principle of the optional implementation mode starts from step 101.

At step 101, distance measuring parameters are set; a wave impedance Z_{cT} and a propagation coefficient γ_{T} of an overhead line are determined; and a wave impedance Z_{cC} and a current propagation coefficient γ_{C} of a cable are determined.

At step 102, voltage values and current values, after an overhead line-cable hybrid transmission line is faulted, of both sides of the line, and voltage values and current values of both sides of the line of one cycle before the line is faulted are collected. Both sides of the line are respectively a side M and a side N.

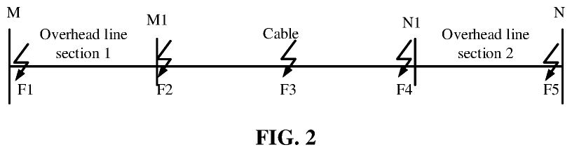

FIG. 2 is a schematic diagram of an overhead line-cable hybrid line according to an optional implementation mode of the present disclosure. As illustrated in FIG. 2, the overhead line-cable hybrid line is divided into a total of three sections, an overhead line section 1 close to the side M of the line, a cable section, and an overhead line section 2 close to the side N of the line. A connection point of the overhead line section 1 and the cable is M₁, and a connection point of the overhead line section 2 and the cable is N₁.

At step 103, voltage value variations are determined according to the collected voltage values of both sides of the line before and after the line is faulted, and current value variations are determined according to the collected current values of both sides of the line before and after the line is faulted.

At step 104, voltage phasor values of both sides of the line are calculated by performing Fourier transformation on the voltage value variations of both sides of the line, and current phasor values of both sides of the line are calculated by performing the Fourier transformation on the current value variations of both sides of the line.

At step 105, voltages Δ\dot{U}_{φMxi} and Δ\dot{U}_{φNxi} of a compensation point are calculated according to a distance xᵢ from the compensation point to the side M of the line after the line is faulted, the voltage phasor values and the current phasor values of both sides of the line, a length L₁ of the overhead line on the side M, a length L₃ of the overhead line on the side N, a length L₂ of the cable, the wave impedance Z_{cT} and the propagation coefficient γ_{T} of the overhead line, and the wave impedance Z_{cC} and the current propagation coefficient γ_{C} of the cable. An initial value of i is 1, and φ is any phase in a three-phase circuit, φ=A,B,C.

At step 106, a distance xᵢ₊₁ from the compensation point to the side M of the line is determined based on a set distance measuring model according to the voltages Δ\dot{U}_{φMxi} and Δ\dot{U}_{φNxi} of the compensation point.

At step 107, i=i+1 is set; it is determined that a distance measuring result is a distance x_{N+1} from the compensation point to the side M of the line in case of i>R; and the step 105 is executed in case of i≤R.

Optionally, before collecting the voltage values and the current values of both sides of the line after the overhead line-cable hybrid transmission line is faulted, the method further includes the following steps: the distance measuring parameters are set, the wave impedance Z_{cT} and the propagation coefficient γ_{T} of the overhead line are determined, and the wave impedance Z_{cC} and the current propagation coefficient γ_{C} of the cable are determined. The distance measuring parameters include a length L of the transmission line, the length L₁ of the overhead line on the side M, the length L₃ of the overhead line on the side N, the length L₂ of the cable, the number R of iterations, and an initial distance x₁ from the compensation point to the side M.

Calculation formulas for the wave impedance Z_{cT} and the propagation coefficient γ_{T} of the overhead line, and the wave impedance Z_{cC} and the current propagation coefficient γ_{C} of the cable are respectively:

$$\begin{matrix}{Z}_{cT} = \sqrt{\frac{{𝓏}_{T}}{{y}_{T}}} , \\ {γ}_{T} = \sqrt{{𝓏}_{T} {y}_{T}} , \\ {Z}_{cC} = \sqrt{\frac{{𝓏}_{C}}{{y}_{C}}} ,\end{matrix}$$

γ_{C}=\sqrt{z_{C}y_{C}};

where z_{T} is a unit impedance of the overhead line; y_{T} is a unit admittance of the overhead line; z_{C} is a unit impedance of the cable; and y_{C} is a unit admittance of the cable.

Optionally, calculation formulas for calculating the voltage value variations according to the collected voltage values of both sides of the line before and after the line is faulted, and calculating the current value variations according to the collected current values of both sides of the line before and after the line is faulted are:

Δu_{φM}(t_{qd}+kT+t)=u_{φM}(t_{qd}+kT+t)−u_{φM}(t_{qd}−T+t),

Δu_{φN}(t_{qd}+kT+t)=u_{φN}(t_{qd}+kT+t)−u_{φN}(t_{qd}−T+t),

Δi_{φM}(t_{qd}+kT+t)=i_{φM}(t_{qd}+kT+t)−i_{φM}(t_{qd}−T+t),

Δi_{φN}(t_{qd}+kT+t)=i_{φN}(t_{qd}+kT+t)−i_{φN}(t_{qd}−T+t).

where both sides of the line are respectively the side M and the side N; t_{qd} is a distance measuring start moment; T is a power frequency cycle, 0<t<T, k≥1, φ=A,B,C; u_{φM}(t_{qd}+kT+t) and u_{φN}(t_{qd}+kT+t)are respectively the collected voltage values of the side M and the side N of the line of phase φ after the fault occurs; u_{φM}(t_{qd}−T+t) and u_{φN}(t_{qd}−T+t) are respectively the collected voltage values of the side M and the side N of the line of phase φ of one cycle before the fault occurs; u_{φM}(t_{qd}+kT+t) and u_{φN}(t_{qd}+kT+t) are respectively the voltage variations of the side M and the side N of the line of phase φ after the phase occurs; i_{φM}(t_{qd}+kT+t) and i_{φN}(t_{qd}+kT+t) are respectively the collected current values of the side M and the side N of the line of phase φ after the fault occurs; i_{φM}(t_{qd}−T+t) and i_{φN}(t_{qd}−kT+t) are respectively the collected current values of the side M and the side N of the line of phase φ of one cycle before the fault occurs; and Δi_{φM}(t_{qd}+kT+t) and Δi_{φN}(t_{qd}+kT+t) are respectively the current variations of the side M and the side N of the line of phase φ after the fault occurs.

Optionally, calculation formulas for calculating the voltages Δ\dot{U}_{φMxi} and ΔU_{φNxi} of the compensation point according to the distance xᵢ from the compensation point to the side M of the line after the line is faulted, the voltage phasor values and the current phasor values of both sides of the line, the length L₁ of the overhead line on the side M, the length L₃ of the overhead line on the side N, the length L₂ of the cable, the wave impedance Z_{cT} and the propagation coefficient γ_{T} of the overhead line, and the wave impedance Z_{cC} and the current propagation coefficient γ_{C} of the cable include as follows.

When the compensation point is at the overhead line section on the side M, the distance from the compensation point to the side M of the line is xᵢ, and the voltages Δ\dot{U}_{φMxi} and Δ\dot{U}_{φNxi} of the compensation point are calculated by using following calculation formulas:

$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ N 1} cosh ( {γ}_{C} {L}_{2} ) - \frac{Δ {\dot{U}}_{φ N 1}}{{Z}_{cC}} sinh ( {γ}_{C} {L}_{2} ) \\ Δ {\dot{U}}_{φ M 1} = Δ {\dot{U}}_{φ N 1} cosh ( {γ}_{C} {L}_{2} ) - Δ {\dot{I}}_{φ N 1} {Z}_{cC} sinh ( {γ}_{C} {L}_{2} )\end{matrix} , \\ \{ \begin{matrix}Δ {\dot{U}}_{φ Mxi} = Δ {\dot{U}}_{φ M} cosh ( {γ}_{T} x ) - Δ {\dot{I}}_{φ M} {Z}_{cT} sinh ( {γ}_{T} x ) \\ Δ {\dot{U}}_{φ Nxi} = Δ {\dot{U}}_{φ M 1} cosh [ {γ}_{T} ( {L}_{1} - x ) ] - Δ {\dot{I}}_{φ M 1} {Z}_{cT} sinh [ {γ}_{T} ( {L}_{1} - x ) ]\end{matrix} .\end{matrix}$$

When the compensation point is at the cable section, the distance from the compensation point to the side M of the line is xᵢ, and the voltages Δ\dot{U}_{φMxi} and Δ\dot{U}_{φNxi} of the compensation point are calculated by using following calculation formulas:

$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} ,\end{matrix}$$

$$\{ \begin{matrix}Δ {\dot{U}}_{φ Mxi} = Δ {\dot{U}}_{φ M 1} cosh [ {γ}_{C} ( x - {L}_{1} ) ] - Δ {\dot{I}}_{φ M 1} {Z}_{cC} sinh [ {γ}_{C} ( x - {L}_{1} ) ] \\ Δ {\dot{U}}_{φ Nxi} = Δ {\dot{U}}_{φ N 1} cosh [ {γ}_{C} ( {L}_{1} + {L}_{2} - x ) ] - Δ {\dot{I}}_{φ N 1} {Z}_{cC} sinh [ {γ}_{C} ( {L}_{1} + {L}_{2} - x ) ]\end{matrix} .$$

When the compensation point is at the overhead line section on the side N, the distance from the compensation point to the side M of the line is xᵢ, and the voltages Δ\dot{U}_{φMxi} and Δ\dot{U}_{φNxi} of the compensation point are calculated by using following calculation formulas:

$$\begin{matrix}\{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} , \\ \{ \begin{matrix}Δ {\dot{I}}_{φ N 1} = Δ {\dot{I}}_{φ M 1} cosh ( {γ}_{C} {L}_{2} ) - \frac{Δ {\dot{U}}_{φ M 1}}{{Z}_{cC}} sinh ( {γ}_{C} {L}_{2} ) \\ Δ {\dot{U}}_{φ N 1} = Δ {\dot{U}}_{φ M 1} cosh ( {γ}_{C} {L}_{2} ) - Δ {\dot{I}}_{φ M 1} {Z}_{cC} sinh ( {γ}_{C} {L}_{2} )\end{matrix} ,\end{matrix}$$

$$\{ \begin{matrix}Δ {\dot{U}}_{φ Mxi} = Δ {\dot{U}}_{φ N 1} cosh [ {γ}_{T} ( x - {L}_{1} - {L}_{2} ) ] - Δ {\dot{I}}_{φ N 1} {Z}_{cT} sinh [ {γ}_{T} ( x - {L}_{1} - {L}_{2} ) ] \\ Δ {\dot{U}}_{φ Nxi} = Δ {\dot{U}}_{φ N} cosh [ {γ}_{T} ( {L}_{1} + {L}_{2} + {L}_{3} - x ) ] - Δ {\dot{I}}_{φ N} {Z}_{cT} sinh [ {γ}_{T} ( {L}_{1} + {L}_{2} + {L}_{3} - x ) ]\end{matrix} ;$$

where M₁ and N₁ are respectively connections between the overhead line of the side M of the line and the cable as well as between the side N of the line and the cable; Δ\dot{U}_{φM1} and Δ\dot{U}_{φN1} are respectively the voltage phasor values at the position M₁ and the position N₁ of the phase φ of the transmission line; Δ\dot{U}_{φM} and Δ\dot{U}_{φN} are respectively the voltage phasor values of the side M and the side N of the phase φ of the transmission line; Δİ_{φM1} and Δİ_{φN1} are respectively the current phasor values at the position M₁ and the position N₁ of the phase φ of the transmission line; Δİ_{φM} and Δİ_{φN} are respectively the current phasor values of the side M and the side N of the phase φ of the transmission line; Δ\dot{U}_{φMxi} is the voltage of the compensation point calculated and determined according to the voltage phasor value and the current phasor value close to the side M of the compensation point; and Δ\dot{U}_{φNxi} is the voltage of the compensation point calculated and determined according to the voltage phasor value and the current phasor value close to the side N of the compensation point.

Optionally, in order to determine the distance xᵢ₊₁ from the compensation point to the side M of the line based on the set distance measuring model according to the voltages Δ\dot{U}_{φMxi} and Δ\dot{U}_{φNxi} of the compensation point, a calculation formula of the distance measuring model is:

$${x}_{i + 1} = \{ \begin{matrix}{x}_{i} - \frac{L}{{2}^{i + 1}} & \vert Δ {\dot{U}}_{φ Mxi} \vert \geq \vert Δ {\dot{U}}_{φ Nxi} \vert \\ {x}_{i} + \frac{L}{{2}^{i + 1}} & \vert Δ {\dot{U}}_{φ Mxi} \vert < \vert Δ {\dot{U}}_{φ Nxi} \vert\end{matrix} ;$$

where L is a length of the transmission line.

A simulation system is constructed by taking the line of FIG. 2 as an example Line fault points F1, F2, F3, F4, and F5 are away from the side M by 0 km, 2.3 km, 10.8 km, 19.3 km and 51.35 km, respectively. Phase-A metallic fault simulation and phase-AB metallic grounding fault simulation are carried out on different positions of the line. The phase A is simulated via a 100Ω transition resistor and distance measuring results and actual fault positions are as illustrated in Table 1.

TABLE 1
Comparison of distance measuring results and actual fault positions of different fault types

| Fault point | F1 | F2 | F3 | F4 | F5 |
|---|---|---|---|---|---|
| Actual position (km) | 0 | 2.3 | 10.8 | 19.3 | 51.35 |
| Phase-A metallic grounding distance | 0.050 | 2.257 | 10.581 | 19.106 | 51.300 |
| measuring result (km) | | | | | |
| Phase-AB metallic grounding distance | 0.050 | 2.257 | 10.681 | 19.306 | 51.200 |
| measuring result (km) | | | | | |
| Grounding distance measuring result of | 0.050 | 2.257 | 10.781 | 19.306 | 51.300 |
| phase A via the 100Ω transition resistor | | | | | |
| (km) | | | | | |

It can be known from Table 1 that the distance measuring results of the fault points calculated according to the method of the present disclosure are close to actual results.

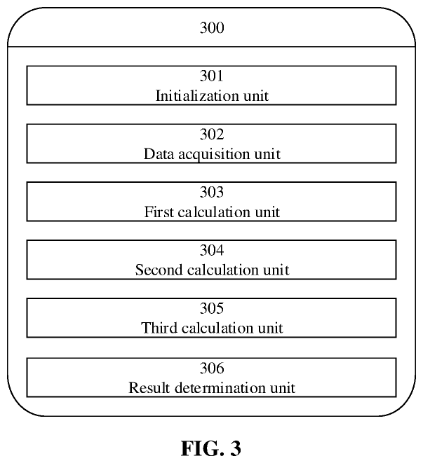

FIG. 3 is a schematic structural diagram of a line double-end steady-state quantity distance measuring system based on an amplitude-comparison principle according to an optional implementation mode of the present disclosure. As illustrated in FIG. 3, a line double-end steady-state quantity distance measuring system 300 based on an amplitude-comparison principle of the optional implementation mode may include: an initialization unit 301, a data acquisition unit 302, a first calculation unit 303, a second calculation unit 304, a third calculation unit 305 and a result determination unit 306.

The initialization unit 301 is configured to set distance measuring parameters, determine a wave impedance Z_{cT} and a propagation coefficient γ_{T} of an overhead line, and determine a wave impedance Z_{cC} and a current propagation coefficient γ_{C} of a cable.

The data acquisition unit 302 is configured to collect voltage values and current values, after an overhead line-cable hybrid transmission line is faulted, of both sides of the line, and voltage values and current values of both sides of the line of one cycle before the line is faulted, where both sides of the line are respectively a side M and a side N.

The first calculation unit 303 is configured to determine voltage value variations according to the collected voltage values of both sides of the line before and after the line is faulted, and determine current value variations according to the collected current values of both sides of the line before and after the line is faulted.

The second calculation unit 304 is configured to calculate voltage phasor values of both sides of the line by performing Fourier transformation on the voltage value variations of both sides of the line, and calculate current phasor values of both sides of the line by performing the Fourier transformation on the current value variations of both sides of the line.

The third calculation unit 305 is configured to calculate voltages Δ\dot{U}_{φMxi} and Δ\dot{U}_{φNxi} of a compensation point according to a distance xᵢ from the compensation point to the side M of the line after the line is faulted, the voltage phasor values and the current phasor values of both sides of the line, a length L₁ of the overhead line on the side M, a length L₃ of the overhead line on the side N, a length L₂ of the cable, the wave impedance Z_{cT} and the propagation coefficient γ_{T} of the overhead line, and the wave impedance Z_{cC} and the current propagation coefficient γ_{C} of the cable, where an initial value of i is 1, and φ is any phase in a three-phase circuit, φ=A,B,C.

The result determination unit 306 is configured to determine a distance xᵢ₊₁ from the compensation point to the side M of the line based on a set distance measuring model according to the voltages Δ\dot{U}_{φMxi} and Δ\dot{U}_{φNxi} of the compensation point, set i=i+1, determine that a distance measuring result is a distance x_{N+1} from the compensation point to the side M of the line in case of i>R, and turn back to the third calculation unit 305 in case of i≤R.

Optionally, the initialization unit 301 is configured to set the distance measuring parameters, determine the wave impedance Z_{cT} and the propagation coefficient γ_{T} of the overhead line, and determine the wave impedance Z_{cC} and the current propagation coefficient γ_{C} of the cable. The distance measuring parameters include a length L of the transmission line, the length L₁ of the overhead line on the side M, the length L₃ of the overhead line on the side N, the length L₂ of the cable, the number R of iterations, and an initial distance x₁ from the compensation point to the side M. Calculation formulas for the wave impedance Z_{cT} and the propagation coefficient γ_{T} of the overhead line, and the wave impedance Z_{cC} and the current propagation coefficient γ_{C} of the cable are respectively:

$$\begin{matrix}{Z}_{cT} = \sqrt{\frac{{𝓏}_{T}}{{y}_{T}}} , \\ {γ}_{T} = \sqrt{{𝓏}_{T} {y}_{T}} , \\ {Z}_{cC} = \sqrt{\frac{{𝓏}_{C}}{{y}_{C}}} ,\end{matrix}$$

γ_{C}=\sqrt{z_{C}y_{C}};

where z_{T} is a unit impedance of the overhead line; y_{T} is a unit admittance of the overhead line; z_{C} is a unit impedance of the cable; and y_{C} is a unit admittance of the cable.

Optionally, the first calculation unit 303 is configured to determine the voltage value variations according to the collected voltage values of both sides of the line before and after the line is faulted, and determine the current value variations according to the collected current values of both sides of the line before and after the line is faulted by using following calculation formulas:

Δu_{φM}(t_{qd}+kT+t)=u_{φM}(t_{qd}+kT+t)−u_{φM}(t_{qd}−T+t),

Δu_{φN}(t_{qd}+kT+t)=u_{φN}(t_{qd}+kT+t)−u_{φN}(t_{qd}−T+t),

Δi_{φM}(t_{qd}+kT+t)=i_{φM}(t_{qd}+kT+t)−i_{φM}(t_{qd}−T+t),

Δi_{φN}(t_{qd}+kT+t)=i_{φN}(t_{qd}+kT+t)−i_{φN}(t_{qd}−T+t).

where both sides of the line are respectively the side M and the side N; t_{qd} is a distance measuring start moment; T is a power frequency cycle, 0<t<T, k≥1, φ=A,B,C; u_{φM}(t_{qd}+kT+t) and u_{φN}(t_{qd}+kT+t) are respectively the collected voltage values of the side M and the side N of the line of phase φ after the fault occurs; u_{φM}(t_{qd}−T+t) and u_{φN}(t_{qd}−T+t) are respectively the collected voltage values of the side M and the side N of the line of phase φ of one cycle before the fault occurs; Δu_{φM}(t_{qd}+kT+t) and Δu_{φN}(t_{qd}+kT+t) are respectively the voltage variations of the side M and the side N of the line of phase φ after the phase occurs; i_{φM}(t_{qd}+kT+t) and i_{φN}(t_{qd}+kT+t) are respectively the collected current values of the side M and the side N of the line of phase φ after the fault occurs; i_{φM}(t_{qd}−T+t) and i_{φN}(t_{qd}−T+t) are respectively the collected current values of the side M and the side N of the line of phase φ of one cycle before the fault occurs; and Δi_{φM}(t_{qd}+kT+t) and Δi_{φN}(t_{qd}+kT+t) are respectively the current variations of the side M and the side N of the line of phase φ after the fault occurs.

Optionally, the third calculation unit 305 is configured to calculate the voltages Δ\dot{U}_{φMxi} and Δ\dot{U}_{φNxi} of the compensation point according to the distance xᵢ from the compensation point to the side M of the line after the line is faulted, the voltage phasor values and the current phasor values of both sides of the line, the length L₁ of the overhead line on the side M, the length L₃ of the overhead line on the side N, the length L₂ of the cable, the wave impedance Z_{cT} and the propagation coefficient γ_{T} of the overhead line, and the wave impedance Z_{cC} and the current propagation coefficient γ_{C} of the cable by using following calculation formulas.

When the compensation point is at the overhead line section on the side M, the distance from the compensation point to the side M of the line is xᵢ, and the voltages Δ\dot{U}_{φMxi} and Δ\dot{U}_{φNxi} of the compensation point are calculated by using following calculation formulas:

$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ N 1} cosh ( {γ}_{C} {L}_{2} ) - \frac{Δ {\dot{U}}_{φ N 1}}{{Z}_{cC}} sinh ( {γ}_{C} {L}_{2} ) \\ Δ {\dot{U}}_{φ M 1} = Δ {\dot{U}}_{φ N 1} cosh ( {γ}_{C} {L}_{2} ) - Δ {\dot{I}}_{φ N 1} {Z}_{cC} sinh ( {γ}_{C} {L}_{2} )\end{matrix} ,\end{matrix}$$

$$\{ \begin{matrix}Δ {\dot{U}}_{φ Mxi} = Δ {\dot{U}}_{φ M} cosh ( {γ}_{T} x ) - Δ {\dot{I}}_{φ M} {Z}_{cT} sinh ( {γ}_{T} x ) \\ Δ {\dot{U}}_{φ Nxi} = Δ {\dot{U}}_{φ M 1} cosh [ {γ}_{T} ( {L}_{1} - x ) ] - Δ {\dot{I}}_{φ M 1} {Z}_{cT} sinh [ {γ}_{T} ( {L}_{1} - x ) ]\end{matrix} .$$

When the compensation point is at the cable section, the distance from the compensation point to the side M of the line is xᵢ, and the voltages Δ\dot{U}_{φMxi} and Δ\dot{U}_{φNxi} of the compensation point are calculated by using following calculation formulas:

$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} ,\end{matrix}$$

$$\{ \begin{matrix}Δ {\dot{U}}_{φ Mxi} = Δ {\dot{U}}_{φ M 1} cos h [ {γ}_{C} ( x - {L}_{1} ) ] - Δ {\dot{I}}_{φ M 1} {Z}_{cC} sin h [ {γ}_{C} ( x - {L}_{1} ) ] \\ Δ {\dot{U}}_{φ Nxi} = Δ {\dot{U}}_{φ N 1} cos h [ {γ}_{C} ( {L}_{1} + {L}_{2} - x ) ] - Δ {\dot{I}}_{φ N 1} {Z}_{cC} sin h [ {γ}_{C} ( {L}_{1} + {L}_{2} - x ) ]\end{matrix} .$$

When the compensation point is at the overhead line section on the side N, the distance from the compensation point to the side M of the line is xᵢ, and the voltages Δ\dot{U}_{φMxi} and Δ\dot{U}_{φNxi} of the compensation point are calculated:

$$\begin{matrix}\{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} , \\ \{ \begin{matrix}Δ {\dot{I}}_{φ N 1} = Δ {\dot{I}}_{φ M 1} cosh ( {γ}_{C} {L}_{2} ) - \frac{Δ {\dot{U}}_{φ M 1}}{{Z}_{cC}} sinh ( {γ}_{C} {L}_{2} ) \\ Δ {\dot{U}}_{φ N 1} = Δ {\dot{U}}_{φ M 1} cosh ( {γ}_{C} {L}_{2} ) - Δ {\dot{I}}_{φ M 1} {Z}_{cC} sinh ( {γ}_{C} {L}_{2} )\end{matrix} ,\end{matrix}$$

$$\{ \begin{matrix}Δ {\dot{U}}_{φ Mxi} = Δ {\dot{U}}_{φ N 1} cosh [ {γ}_{T} ( x - {L}_{1} - {L}_{2} ) ] - Δ {\dot{I}}_{φ N 1} {Z}_{cT} sinh [ {γ}_{T} ( x - {L}_{1} - {L}_{2} ) ] \\ Δ {\dot{U}}_{φ Nxi} = Δ {\dot{U}}_{φ N} cosh [ {γ}_{T} ( {L}_{1} + {L}_{2} + {L}_{3} - x ) ] - Δ {\dot{I}}_{φ N} {Z}_{cT} sinh [ {γ}_{T} ( {L}_{1} + {L}_{2} + {L}_{3} - x ) ]\end{matrix} ;$$

where M₁ and N₁ are respectively connections between the overhead line of the side M of the line and the cable as well as between the side N of the line and the cable; Δ\dot{U}_{φM1} and Δ\dot{U}_{φN1} are respectively the voltage phasor values at the position M₁ and the position N₁ of the phase φ of the transmission line; ΔU_{φM} and Δ\dot{U}_{φN} are respectively the voltage phasor values of the side M and the side N of the phase φ of the transmission line; Δİ_{φM1} and Δİ_{φN1} are respectively the current phasor values at the position M₁ and the position N₁ of the phase φ of the transmission line; Δİ_{φM} and Δİ_{φN} are respectively the current phasor values of the side M and the side N of the phase φ of the transmission line; Δ\dot{U}_{φMxi} is the voltage of the compensation point calculated and determined according to the voltage phasor value and the current phasor value close to the side M of the compensation point; and Δ\dot{U}_{φNxi} is the voltage of the compensation point calculated and determined according to the voltage phasor value and the current phasor value close to the side N of the compensation point.

Optionally, the result determination unit 306 is configured to determine the distance xᵢ₊₁ from the compensation point to the side M of the line based on the set distance measuring model according to the voltages Δ\dot{U}_{φMxi} and Δ\dot{U}_{φNxi} of the compensation point by using a following calculation formula:

$${x}_{i + 1} \{ \begin{matrix}{x}_{i} - \frac{L}{{2}^{i + 1}} & \vert Δ {\dot{U}}_{φ Mxi} \vert \geq \vert Δ {\dot{U}}_{φ Nxi} \vert \\ {x}_{i} + \frac{L}{{2}^{i + 1}} & \vert Δ {\dot{U}}_{φ Mxi} \vert < \vert Δ {\dot{U}}_{φ Nxi} \vert\end{matrix} ;$$

where L is a length of the transmission line.

The distance measuring steps of the line double-end steady-state quantity distance measuring system based on the amplitude-comparison principle for the overhead line-cable hybrid line are the same as the steps used in the line double-end steady-state quantity distance measuring method based on the amplitude-comparison principle, and technical effects achieved are also the same, so descriptions thereof are omitted.

The present disclosure has been described by the above implementation modes. However, as is well known to those skilled in the art, as defined by the appended patent claims, other embodiments than those disclosed above in the present disclosure equally fall within the scope of the present disclosure.

Generally, all terms used in the claims are interpreted according to their ordinary meanings in the technical art, unless explicitly defined otherwise therein. All references to “a/the/the [apparatus, assembly, etc.]” are openly interpreted as at least one example of the apparatus, component, etc., unless explicitly stated otherwise. The steps of any method disclosed herein need not be run in the exact order disclosed, unless explicitly stated.

Those skilled in the art should understand that the embodiments of the present disclosure may be methods, systems or computer program products. Therefore, the present disclosure may adopt the form of a complete hardware embodiment, a complete software embodiment, or a software and hardware combination embodiment. In addition, the present disclosure may use the form of a computer program product implemented on one or multiple computer-sensitive storage media (including a magnetic disk memory, a compact disc read-only memory (CD-ROM), an optical memory and the like) including computer-sensitive program codes.

The present disclosure is described by referring to flowcharts and/or block diagrams of methods, devices (systems) and computer program products according to the embodiments of the present disclosure. It is worthwhile to note that computer program instructions can be used to implement each process and/or each block in the flowcharts and/or the block diagrams and a combination of a process and/or a block in the flowcharts and/or the block diagrams. These computer program instructions can be provided for a general-purpose computer, a dedicated computer, an embedded processor, or a processor of another programmable data processing device to generate a machine, so that the instructions executed by the computer or the processor of the another programmable data processing device generate an apparatus for implementing a specified function in one or more processes in the flowcharts and/or in one or more blocks in the block diagrams.

Alternatively, these computer program instructions can be stored in a computer-readable memory that can instruct the computer or the another programmable data processing device to work in a specific way, so that the instructions stored in the computer-readable memory generate an artifact that includes an instruction apparatus. The instruction apparatus implements a specified function in one or more processes in the flowcharts and/or in one or more blocks in the block diagrams.

Alternatively, these computer program instructions can be loaded onto the computer or the another programmable data processing device, so that a series of operations and steps are performed on the computer or the another programmable device, thereby generating computer-implemented processing. Therefore, the instructions executed on the computer or the another programmable device provide steps for implementing a specified function in one or more processes in the flowcharts and/or in one or more blocks in the block diagrams.

The line double-end steady-state quantity distance measuring method and system based on the amplitude-comparison principle provided by the technical solutions of the present disclosure determine the position of a short-circuit point by means of iteratively calculating voltages of the short-circuit point after collecting the voltage values and the current values of both sides of the line before and after the fault occurs, calculating the voltage variations and the current variations of both sides of the line, and determining the voltage phasor values and the current phasor values according to the voltage variations and the current variations. The method has a simple principle and can accurately identify a fault point and realize accurate distance measuring of the line.

1. A line double-end steady-state quantity distance measuring method based on an amplitude-comparison principle, comprising:
at step 1, collecting voltage values and current values, after an overhead line-cable hybrid transmission line is faulted, of both sides of the line, and voltage values and current values of both sides of the line of one cycle before the line is faulted; wherein both sides of the line are respectively a side M and a side N;
at step 2, determining voltage value variations according to the collected voltage values of both sides of the line before and after the line is faulted, and determining current value variations according to the collected current values of both sides of the line before and after the line is faulted;
at step 3, calculating voltage phasor values of both sides of the line by performing Fourier transformation on the voltage value variations of both sides of the line, and calculating current phasor values of both sides of the line by performing the Fourier transformation on the current value variations of both sides of the line;
at step 4, calculating voltages Δ\dot{U}_{φMxi} and Δ\dot{U}_{φNxi} of a compensation point according to a distance xᵢ from the compensation point to the side M of the line after the line is faulted, the voltage phasor values and the current phasor values of both sides of the line, a length L₁ of an overhead line on the side M, a length L₃ of an overhead line on the side N, a length L₂ of a cable, a wave impedance Z_{cT} and a propagation coefficient γ_{T} of the overhead line, and a wave impedance Z_{cC} and a current propagation coefficient γ_{C} of the cable; wherein an initial value of i is 1, and φ is any phase in a three-phase circuit, φ=A,B,C;
at step 5, determining a distance xᵢ₊₁ from the compensation point to the side M of the line based on a set distance measuring model according to the voltages Δ\dot{U}_{φMxi} and Δ\dot{U}_{φNxi} of the compensation point; and
at step 6, setting i=i+1; determining that a distance measuring result is a distance x_{N+1} from the compensation point to the side M of the line in case of i>R; and turning back to the step 4 in case of i≤R; wherein R is a number of iterations.

2. The method of claim 1, wherein before collecting the voltage values and the current values of both sides of the line after the overhead line-cable hybrid transmission line is faulted, further comprising:
setting distance measuring parameters, determining the wave impedance Z_{cT} and the propagation coefficient γ_{T} of the overhead line, and determining the wave impedance Z_{cC} and the current propagation coefficient γ_{C} of the cable; wherein the distance measuring parameters comprise a length L of the transmission line, the length L₁ of the overhead line on the side M, the length L₃ of the overhead line on the side N, the length L₂ of the cable, the number R of iterations, and an initial distance x₁ from the compensation point to the side M;
wherein calculation formulas for the wave impedance Z_{cT} and the propagation coefficient γ_{T} of the overhead line, and the wave impedance Z_{cC} and the current propagation coefficient γ_{C} of the cable are respectively:
$$\begin{matrix}{Z}_{cT} = \sqrt{\frac{{𝓏}_{T}}{{y}_{T}}} , \\ {γ}_{T} = \sqrt{{𝓏}_{T} {y}_{T}} , \\ {Z}_{cC} = \sqrt{\frac{{𝓏}_{C}}{{y}_{C}}} ,\end{matrix}$$
γ_{C}=\sqrt{z_{C}y_{C}};
wherein z_{T} is a unit impedance of the overhead line; y_{T} is a unit admittance of the overhead line; z_{C} is a unit impedance of the cable; and y_{C} is a unit admittance of the cable.

3. The method of claim 1, wherein calculation formulas for calculating the voltage value variations according to the collected voltage values of both sides of the line before and after the line is faulted, and calculating the current value variations according to the collected current values of both sides of the line before and after the line is faulted are:
Δu_{φM}(t_{qd}+kT+t)=u_{φM}(t_{qd}+kT+t)−u_{φM}(t_{qd}−T+t),
Δu_{φN}(t_{qd}+kT+t)=u_{φN}(t_{qd}+kT+t)−u_{φN}(t_{qd}−T+t),
Δi_{φM}(t_{qd}+kT+t)=i_{φM}(t_{qd}+kT+t)−i_{φM}(t_{qd}−T+t),
Δi_{φN}(t_{qd}+kT+t)=i_{φN}(t_{qd}+kT+t)−i_{φN}(t_{qd}−T+t);
wherein both sides of the line are respectively the side M and the side N; t_{qd} is a distance measuring start moment; T is a power frequency cycle, 0<t<T , k≥1, φ=A,B,C; u_{φM}(t_{qd}+kT+t) and u_{φN}(t_{qd}+kT+t) are respectively the collected voltage values of the side M and the side N of the line of phase φ after the fault occurs; u_{φM}(t_{qd}−T+t) and u_{φN}(t_{qd}−T+t) are respectively the collected voltage values of the side M and the side N of the line of phase φ of one cycle before the fault occurs; Δu_{φM}(t_{qd}+kT+t) and uΔ_{φN}(t_{qd}+kT+t) are respectively the voltage variations of the side M and the side N of the line of phase φ after the phase occurs; i_{φM}(t_{qd}+kT+t) and i_{φN}(t_{qd}+kT+t) are respectively the collected current values of the side M and the side N of the line of phase φ after the fault occurs; i_{φM}(t_{qd}−T+t) and i_{φN}(t_{qd}−T+t) are respectively the collected current values of the side M and the side N of the line of phase φ of one cycle before the fault occurs; and Δi_{φM}(t_{qd}+kT+t) and Δi_{φN}(t_{qd}+kT+t) are respectively the current variations of the side M and the side N of the line of phase φ after the fault occurs.

4. The method of claim 2, wherein calculation formulas for calculating the voltages Δ\dot{U}_{φMxi} and Δ\dot{U}_{φNxi} of the compensation point according to the distance xᵢ from the compensation point to the side M of the line after the line is faulted, the voltage phasor values and the current phasor values of both sides of the line, the length L₁ of the overhead line on the side M, the length L₃ of the overhead line on the side N, the length L₂ of the cable, the wave impedance Z_{cT} and the propagation coefficient γ_{T} of the overhead line, and the wave impedance Z_{cC} and the current propagation coefficient γ_{C} of the cable comprises:
when the compensation point is at an overhead line section on the side M, the distance from the compensation point to the side M of the line is xᵢ, and the voltages Δ\dot{U}_{φMxi} and Δ\dot{U}_{φNxi} of the compensation point are calculated by using following calculation formulas:
$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ N 1} cosh ( {γ}_{C} {L}_{2} ) - \frac{Δ {\dot{U}}_{φ N 1}}{{Z}_{cC}} sinh ( {γ}_{C} {L}_{2} ) \\ Δ {\dot{U}}_{φ M 1} = Δ {\dot{U}}_{φ N 1} cosh ( {γ}_{C} {L}_{2} ) - Δ {\dot{I}}_{φ N 1} {Z}_{cC} sinh ( {γ}_{C} {L}_{2} )\end{matrix} ,\end{matrix}$$
$$\{ \begin{matrix}Δ {\dot{U}}_{φ Mxi} = Δ {\dot{U}}_{φ M} cosh ( {γ}_{T} x ) - Δ {\dot{I}}_{φ M} {Z}_{cT} sinh ( {γ}_{T} x ) \\ Δ {\dot{U}}_{φ Nxi} = Δ {\dot{U}}_{φ M 1} cosh [ {γ}_{T} ( {L}_{1} - x ) ] - Δ {\dot{I}}_{φ M 1} {Z}_{cT} sinh [ {γ}_{T} ( {L}_{1} - x ) ]\end{matrix} ;$$
when the compensation point is at a cable section, the distance from the compensation point to the side M of the line is xᵢ, and the voltages Δ\dot{U}_{φMxi} and Δ\dot{U}_{φNxi} of the compensation point are calculated by using following calculation formulas:
$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} ,\end{matrix}$$
$$\{ \begin{matrix}Δ {\dot{U}}_{φ Mxi} = Δ {\dot{U}}_{φ M 1} cosh [ {γ}_{C} ( x - {L}_{1} ) ] - Δ {\dot{I}}_{φ M 1} {Z}_{cC} sinh [ {γ}_{C} ( x - {L}_{1} ) ] \\ Δ {\dot{U}}_{φ Nxi} = Δ {\dot{U}}_{φ N 1} cosh [ {γ}_{C} ( {L}_{1} + {L}_{2} - x ) ] - Δ {\dot{I}}_{φ N 1} {Z}_{cC} sinh [ {γ}_{C} ( {L}_{1} + {L}_{2} - x ) ]\end{matrix} ;$$
when the compensation point is at the overhead line section on the side N, the distance from the compensation point to the side M of the line is xᵢ, and the voltages Δ\dot{U}_{φMxi} and Δ\dot{U}_{φNxi} of the compensation point are calculated by using following calculation formulas:
$$\begin{matrix}\{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} , \\ \{ \begin{matrix}Δ {\dot{I}}_{φ N 1} = Δ {\dot{I}}_{φ M 1} cosh ( {γ}_{C} {L}_{2} ) - \frac{Δ {\dot{U}}_{φ M 1}}{{Z}_{cC}} sinh ( {γ}_{C} {L}_{2} ) \\ Δ {\dot{U}}_{φ N 1} = Δ {\dot{U}}_{φ M 1} cosh ( {γ}_{C} {L}_{2} ) - Δ {\dot{I}}_{φ M 1} {Z}_{cC} sinh ( {γ}_{C} {L}_{2} )\end{matrix} ,\end{matrix}$$
$$\{ \begin{matrix}Δ {\dot{U}}_{φ Mxi} = Δ {\dot{U}}_{φ N 1} cosh [ {γ}_{T} ( x - {L}_{1} - {L}_{2} ) ] - Δ {\dot{I}}_{φ N 1} {Z}_{cT} sinh [ {γ}_{T} ( x - {L}_{1} - {L}_{2} ) ] \\ Δ {\dot{U}}_{φ Nxi} = Δ {\dot{U}}_{φ N} cosh [ {γ}_{T} ( {L}_{1} + {L}_{2} + {L}_{3} - x ) ] - Δ {\dot{I}}_{φ N} {Z}_{cT} sinh [ {γ}_{T} ( {L}_{1} + {L}_{2} + {L}_{3} - x ) ]\end{matrix} ;$$
wherein M₁ and N₁ are respectively connections between the overhead line of the side M of the line and the cable as well as between the side N of the line and the cable; Δ\dot{U}_{φM1} and Δ\dot{U}_{φN1} are respectively the voltage phasor values at the position M₁ and the position N₁ of the phase φ of the transmission line; Δ\dot{U}_{φM} and Δ\dot{U}_{φN} are respectively the voltage phasor values of the side M and the side N of the phase φ of the transmission line; Δİ_{φM1} and Δİ_{φN1} are respectively the current phasor values at the position M₁ and the position N₁ of the phase φ of the transmission line; Δİ_{φM} and Δİ_{φN} are respectively the current phasor values of the side M and the side N of the phase φ of the transmission line; Δ\dot{U}_{φMxi} is the voltage of the compensation point calculated and determined according to the voltage phasor value and the current phasor value close to the side M of the compensation point; and Δ\dot{U}_{φNxi} is the voltage of the compensation point calculated and determined according to the voltage phasor value and the current phasor value close to the side N of the compensation point.

5. The method of claim 2, wherein during determining the distance xᵢ₊₁ from the compensation point to the side M of the line based on the set distance measuring model according to the voltages Δ\dot{U}_{φMxi} and Δ\dot{U}_{φNxi} of the compensation point, a calculation formula of the distance measuring model is:
$${x}_{i + 1} \{ \begin{matrix}{x}_{i} - \frac{L}{{2}^{i + 1}} & \vert Δ {\dot{U}}_{φ Mxi} \vert \geq \vert Δ {\dot{U}}_{φ Nxi} \vert \\ {x}_{i} + \frac{L}{{2}^{i + 1}} & \vert Δ {\dot{U}}_{φ Mxi} \vert < \vert Δ {\dot{U}}_{φ Nxi} \vert\end{matrix} ;$$
wherein L is a length of the transmission line.

6. A line double-end steady-state quantity distance measuring system based on an amplitude-comparison principle, comprising:
a data acquisition component, configured to collect voltage values and current values, after an overhead line-cable hybrid transmission line is faulted, of both sides of the line, and voltage values and current values of both sides of the line of one cycle before the line is faulted; wherein both sides of the line are respectively a side M and a side N;
a first calculator, configured to determine voltage value variations according to the collected voltage values of both sides of the line before and after the line is faulted, and determine current value variations according to the collected current values of both sides of the line before and after the line is faulted;
a second calculator, configured to calculate voltage phasor values of both sides of the line by performing Fourier transformation on the voltage value variations of both sides of the line, and calculate current phasor values of both sides of the line by performing the Fourier transformation on the current value variations of both sides of the line;
a third calculator, configured to calculate voltages Δ\dot{U}_{φMxi} and Δ\dot{U}_{φNxi} of a compensation point according to a distance xᵢ from the compensation point to the side M of the line after the line is faulted, the voltage phasor values and the current phasor values of both sides of the line, a length L₁ of an overhead line on the side M, a length L₃ of an overhead line on the side N, a length L₂ of a cable, a wave impedance Z_{cT} and a propagation coefficient γ_{T} of the overhead line, and a wave impedance Z_{cC} and a current propagation coefficient γ_{C} of the cable; wherein an initial value of i is 1, and φ is any phase in a three-phase circuit, φ=A,B,C; and
a result determination component, configured to determine a distance xᵢ₊₁ from the compensation point to the side M of the line based on a set distance measuring model according to the voltages Δ\dot{U}_{φMxi} and Δ\dot{U}_{φNxi} of the compensation point, set i=i+1, determine that a distance measuring result is a distance x_{N+1} from the compensation point to the side M of the line in case of i>R, and turn back to the third calculator in case of i≤R; wherein R is a number of iterations.

7. The system of claim 6, further comprising an initialization component; wherein the initialization component is configured to set distance measuring parameters, determine the wave impedance Z_{cT} and the propagation coefficient γ_{T} of the overhead line, and determine the wave impedance Z_{cC} an the current propagation coefficient γ_{C} of the cable; wherein the distance measuring parameters comprises a length L of the transmission line, the length L₁ of the overhead line on the side M, the length L₃ of the overhead line on the side N, the length L₂ of the cable, the number R of iterations, and an initial distance x₁ from the compensation point to the side M;
wherein calculation formulas for the wave impedance Z_{cT} and the propagation coefficient γ_{T} of the overhead line, and the wave impedance Z_{cC} and the current propagation coefficient γ_{C} of the cable are respectively:
$$\begin{matrix}{Z}_{cT} = \sqrt{\frac{{𝓏}_{T}}{{y}_{T}}} , \\ {γ}_{T} = \sqrt{{𝓏}_{T} {y}_{T}} , \\ {Z}_{cC} = \sqrt{\frac{{𝓏}_{C}}{{y}_{C}}} ,\end{matrix}$$
γ_{C}=\sqrt{z_{C}y_{C}};
wherein z_{T} is a unit impedance of the overhead line; y_{T} is a unit admittance of the overhead line; z_{C} is a unit impedance of the cable; and y_{C} is a unit admittance of the cable.

8. The system of claim 6, wherein the first calculator is configured to use calculation formulas:
Δu_{φM}(t_{qd}+kT+t)=u_{φM}(t_{qd}+kT+t)−u_{φM}(t_{qd}−T+t),
Δu_{φN}(t_{qd}+kT+t)=u_{φN}(t_{qd}+kT+t)−u_{φN}(t_{qd}−T+t),
Δi_{φM}(t_{qd}+kT+t)=i_{φM}(t_{qd}+kT+t)−i_{φM}(t_{qd}−T+t),
Δi_{φN}(t_{qd}+kT+t)=i_{φN}(t_{qd}+kT+t)−i_{φN}(t_{qd}−T+t);
wherein both sides of the line are respectively the side M and the side N; t_{qd} is a distance measuring start moment; T is a power frequency cycle, 0<t<T, k≥1, φ=A,B,C; u_{φM}(t_{qd}+kT+t) and u_{φN}(t_{qd}+kT+t) are respectively the collected voltage values of the side M and the side N of the line of phase φ after the fault occurs; u_{φM}(t_{qd}−T+t) and u_{φN}(t_{qd}−T+t) are respectively the collected voltage values of the side M and the side N of the line of phase φ of one cycle before the fault occurs; Δu_{φM}(t_{qd}+kT+t) and Δu_{φN}(t_{qd}+kT+t) are respectively the voltage variations of the side M and the side N of the line of phase φ after the phase occurs; i_{φM}(t_{qd}+kT+t) and i_{φN}(t_{qd}+kT+t) are respectively the collected current values of the side M and the side N of the line of phase φ after the fault occurs; i_{φM}(t_{qd}−T+t) and i_{φN}(t_{qd}−T+t) are respectively the collected current values of the side M and the side N of the line of phase φ of one cycle before the fault occurs; and Δi_{φM}(t_{qd}+kT+t) and Δi_{φN}(t_{qd}+kT+t) are respectively the current variations of the side M and the side N of the line of phase φ after the fault occurs.

9. The system of claim 7, wherein the third calculator is configured to use calculation formulas:
when the compensation point is at the overhead line section on the side M, the distance from the compensation point to the side M of the line is xᵢ, and the voltages Δ\dot{U}_{φMxi} and Δ\dot{U}_{φNxi} of the compensation point are calculated by using following calculation formulas:
$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ N 1} cosh ( {γ}_{C} {L}_{2} ) - \frac{Δ {\dot{U}}_{φ N 1}}{{Z}_{cC}} sinh ( {γ}_{C} {L}_{2} ) \\ Δ {\dot{U}}_{φ M 1} = Δ {\dot{U}}_{φ N 1} cosh ( {γ}_{C} {L}_{2} ) - Δ {\dot{I}}_{φ N 1} {Z}_{cC} sinh ( {γ}_{C} {L}_{2} )\end{matrix} ,\end{matrix}$$
$$\{ \begin{matrix}Δ {\dot{U}}_{φ Mxi} = Δ {\dot{U}}_{φ M} cosh ( {γ}_{T} x ) - Δ {\dot{I}}_{φ M} {Z}_{cT} sinh ( {γ}_{T} x ) \\ Δ {\dot{U}}_{φ Nxi} = Δ {\dot{U}}_{φ M 1} cosh [ {γ}_{T} ( {L}_{1} - x ) ] - Δ {\dot{I}}_{φ M 1} {Z}_{cT} sinh [ {γ}_{T} ( {L}_{1} - x ) ]\end{matrix} ;$$
when the compensation point is at the cable section, the distance from the compensation point to the side M of the line is xᵢ, and the voltages Δ\dot{U}_{φMxi} and Δ\dot{U}_{φNxi} of the compensation point are calculated by using following calculation formulas:
$$\begin{matrix}\{ \begin{matrix}Δ {\dot{I}}_{φ N 1} = Δ {\dot{I}}_{φ N} cosh ( {γ}_{T} {L}_{3} ) - \frac{Δ {\dot{U}}_{φ N}}{{Z}_{cT}} sinh ( {γ}_{T} {L}_{3} ) \\ Δ {\dot{U}}_{φ N 1} = Δ {\dot{U}}_{φ N} cosh ( {γ}_{T} {L}_{3} ) - Δ {\dot{I}}_{φ N} {Z}_{cT} sinh ( {γ}_{T} {L}_{3} )\end{matrix} , \\ \{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} ,\end{matrix}$$
$$\{ \begin{matrix}Δ {\dot{U}}_{φ Mxi} = Δ {\dot{U}}_{φ M 1} cosh [ {γ}_{C} ( x - {L}_{1} ) ] - Δ {\dot{I}}_{φ M 1} {Z}_{cC} sinh [ {γ}_{C} ( x - {L}_{1} ) ] \\ Δ {\dot{U}}_{φ Nxi} = Δ {\dot{U}}_{φ N 1} cosh [ {γ}_{C} ( {L}_{1} + {L}_{2} - x ) ] - Δ {\dot{I}}_{φ N 1} {Z}_{cC} sinh [ {γ}_{C} ( {L}_{1} + {L}_{2} - x ) ]\end{matrix} ;$$
when the compensation point is at the overhead line section on the side N, the distance from the compensation point to the side M of the line is xᵢ, and the voltages Δ\dot{U}_{φMxi} and Δ\dot{U}_{φNxi} of the compensation point are calculated by using following calculation formulas:
$$\begin{matrix}\{ \begin{matrix}Δ {\dot{I}}_{φ M 1} = Δ {\dot{I}}_{φ M} cosh ( {γ}_{T} {L}_{1} ) - \frac{Δ {\dot{U}}_{φ M}}{{Z}_{cT}} sinh ( {γ}_{T} {L}_{1} ) \\ Δ {\dot{U}}_{φ M 1} = Δ {\dot{U}}_{φ M} cosh ( {γ}_{T} {L}_{1} ) - Δ {\dot{I}}_{φ M} {Z}_{cT} sinh ( {γ}_{T} {L}_{1} )\end{matrix} , \\ \{ \begin{matrix}Δ {\dot{I}}_{φ N 1} = Δ {\dot{I}}_{φ M 1} cosh ( {γ}_{C} {L}_{2} ) - \frac{Δ {\dot{U}}_{φ M 1}}{{Z}_{cC}} sinh ( {γ}_{C} {L}_{2} ) \\ Δ {\dot{U}}_{φ N 1} = Δ {\dot{U}}_{φ M 1} cosh ( {γ}_{C} {L}_{2} ) - Δ {\dot{I}}_{φ M 1} {Z}_{cC} sinh ( {γ}_{C} {L}_{2} )\end{matrix} ,\end{matrix}$$
$$\{ \begin{matrix}Δ {\dot{U}}_{φ Mxi} = Δ {\dot{U}}_{φ N 1} cosh [ {γ}_{T} ( x - {L}_{1} - {L}_{2} ) ] - Δ {\dot{I}}_{φ N 1} {Z}_{cT} sinh [ {γ}_{T} ( x - {L}_{1} - {L}_{2} ) ] \\ Δ {\dot{U}}_{φ Nxi} = Δ {\dot{U}}_{φ N} cosh [ {γ}_{T} ( {L}_{1} + {L}_{2} + {L}_{3} - x ) ] - Δ {\dot{I}}_{φ N} {Z}_{cT} sinh [ {γ}_{T} ( {L}_{1} + {L}_{2} + {L}_{3} - x ) ]\end{matrix} ;$$
wherein M₁ and N₁ are respectively connections between the overhead line of the side M of the line and the cable as well as between the side N of the line and the cable; Δ\dot{U}_{φM1} and Δ\dot{U}_{φN1} are respectively the voltage phasor values at the position M₁ and the position N₁ of the phase φ of the transmission line; Δ\dot{U}_{φM} and Δ\dot{U}_{φN} are respectively the voltage phasor values of the side M and the side N of the phase φ of the transmission line; Δİ_{φM1} and Δİ_{φN1} are respectively the current phasor values at the position M₁ and the position N₁ of the phase φ of the transmission line; Δİ_{φM} and Δİ_{φN} are respectively the current phasor values of the side M and the side N of the phase φ of the transmission line; Δ\dot{U}_{φMxi} is the voltage of the compensation point calculated and determined according to the voltage phasor value and the current phasor value close to the side M of the compensation point; and Δ\dot{U}_{φNxi} is the voltage of the compensation point calculated and determined according to the voltage phasor value and the current phasor value close to the side N of the compensation point.

10. The system of claim 7, wherein a calculation formula, adopted by the result determination component, for the distance measuring model is:
$${x}_{i + 1} \{ \begin{matrix}{x}_{i} - \frac{L}{{2}^{i + 1}} & \vert Δ {\dot{U}}_{φ Mxi} \vert \geq \vert Δ {\dot{U}}_{φ Nxi} \vert \\ {x}_{i} + \frac{L}{{2}^{i + 1}} & \vert Δ {\dot{U}}_{φ Mxi} \vert < \vert Δ {\dot{U}}_{φ Nxi} \vert\end{matrix} ;$$
wherein L is a length of the transmission line.
